(19) United States
(12) Patent Application Publication
(10) Pub. No.: US 2007/0247206 A1
(43) Pub. Date: Oct. 25, 2007

(54) Programmable trigger delays

(76) Inventors: Dietrich Werner Vook, Los Altos, CA (US); Stanley Ted Jefferson, Palo Alto, CA (US); Vamsi Krishna Srikantam, Fremont, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/408,400

(22) Filed: Apr. 21, 2006

(51) Int. Cl. H03H 11/26

(52) U.S. Cl. 327/261

(57) ABSTRACT

Aspects of the disclosure embody methods and circuits for delaying a trigger signal. In one embodiment, a trigger delay circuit receives a trigger-in signal, delays some predetermined and programmable time delay and then outputs a trigger-out signal. The trigger delay circuit, in one embodiment, includes a programmable trigger circuit that time stamps the input trigger signal, delay for a predetermined time, and output the output trigger signal after the predetermined time.

### BACKGROUND

Many electronic systems span large spatial extent, such as military radar or aircraft control systems. While signals in these systems are transmitted at or near the speed of light, a delay does occur between the transmission and receipt of the signals. Sending signals that must be output at certain, predetermined times is very difficult in such geographically dispersed systems. Generally, the delay in the system is determined by measuring the delay with a test system. The delay is then accounted for when sending the command.

When new hardware is introduced into the large system, the delay problems are compounded because the system must compensate for new instrument and cable delays. Faster or slower instruments or longer or shorter cables generally cause the new or modified delays.

### SUMMARY

In general terms, this document is directed to synchronizeable and programmable trigger delays that enable high time resolution, small minimum delays and large maximum delays.

One aspect is a trigger delay circuit that includes a programmable trigger circuit. The programmable trigger circuit is operable to receive one or more input trigger signals and output one or more output trigger signals. The programmable trigger circuit is also operable to delay the time between receiving the input trigger signal and outputting the output trigger signal by some programmable delay.

Another aspect is a trigger delay circuit that includes a receive circuit, a trigger circuit and a delay generator circuit. The receive circuit receives an input trigger signal. The trigger circuit is operable to output an output trigger signal. Connected between the receive circuit and the trigger circuit, the delay generator circuit is operable to determine when the input trigger signal is received and delay the output of the output trigger signal for a predetermined time delay provided by a delay signal.

Still another aspect is a method for delaying a trigger signal. The method includes receiving an input trigger signal and determining a delay between the receipt of the input trigger signal and the output of the output trigger signal. A delay signal is sent to delay the output trigger signal in accordance with the determined delay. In response to the delay signal, the output of the output trigger signal is delayed and the sent after the delay.

### BRIEF DESCRIPTION OF THE DRAWINGS

FIG. 1 is a block diagram of an embodiment of a programmable trigger delay circuit.

FIG. 2 is a schematic block diagram of another embodiment of a programmable trigger delay circuit under control of a central processing unit (CPU).

FIG. 3 is a block diagram of an embodiment of a programmable trigger delay system using multiple programmable trigger circuits to provide multiple possible delays for several trigger-out signals.

FIG. 5 is a schematic diagram of an embodiment of a delay circuit operable in the programmable trigger circuit.

FIG. 6 is a schematic diagram of another embodiment of a delay circuit operable in the programmable trigger circuit.

FIG. 7 is a schematic diagram of another embodiment of a delay circuitry operable in the programmable trigger circuit.

FIG. 8 shows an embodiment of a method for delaying a trigger-out signal using a programmable trigger circuit.

### DETAILED DESCRIPTION

Various embodiments will be described in detail with reference to the drawings, wherein like reference numerals represent like parts and assemblies throughout the several views. Reference to various embodiments in this specification does not limit the scope of the claims attached hereto. Any examples set forth in this specification merely set forth some of the many possible embodiments for the appended claims.

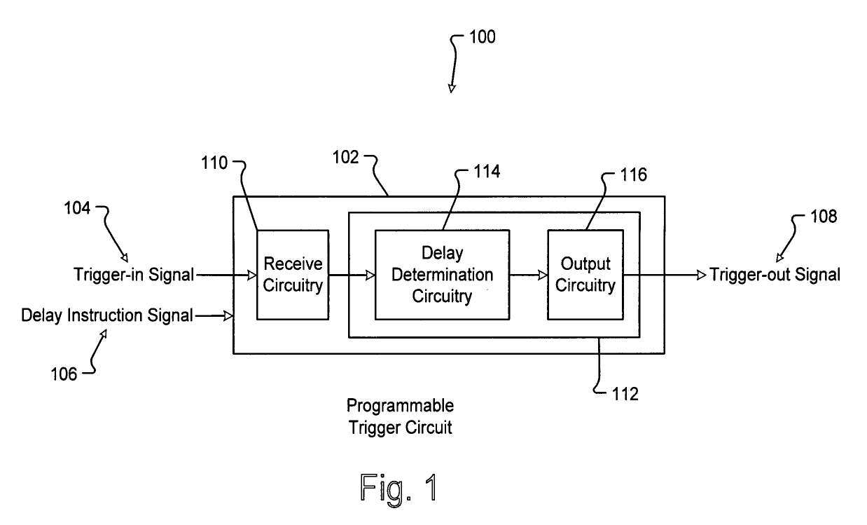

In an exemplary embodiment, a trigger delay circuit 100, as shown in FIG. 1, allows for systems, like those mentioned above, to receive input signals and automatically adjust the time the output signals are transmitted. The trigger delay circuit 100 receives a trigger-in signal 104, waits some predetermined and programmable time delay, and then outputs a trigger-out signal 108. In the exemplary embodiment, the trigger delay circuit 100 comprises a programmable trigger circuit 102. The programmable trigger circuit 102 receives the trigger-in signal 104 and outputs the trigger-out signal 108. In further embodiments, the programmable trigger circuit includes a receive circuitry 110 that receives the trigger-in signal 104 and sends the trigger signal to a delay circuitry 112. The delay circuitry delays the trigger and outputs the trigger-out signal 108.

In one embodiment, the delay circuitry 112 includes a delay determination circuitry 114 and an output circuitry 116. The delay determination circuitry 114 determines a time at which to output the trigger-out signal, and the output circuitry 116 outputs the trigger-out signal 108 at the time determined by the delay determination circuitry 114. The time at which the trigger-out signal 108 is determined to be output is based on a clock. The output circuitry 112, in some embodiments, outputs the trigger-out signal based on the time the trigger-in signal 104 is received plus some added delay or time differential. The delay is based on a local clock used for the hardware operation.

The programmable trigger circuit 102, in one embodiment, also receives a delay instruction signal 106, which provides the programmable time delay information for delaying the output of the trigger-out signal 108. In the exemplary embodiment, the delay circuitry 112 provides a small minimum delay and a large maximum delay. Additionally, in further embodiments, the receive circuitry 110 receives and time stamps the trigger-in signal 104 at a high time resolution, and the delay circuitry 112 outputs the trigger-out signal 108 also at a high time resolution. The high time resolution can be to a fraction of the period of the oscillator driving the logic.

In one embodiment, to time stamp the trigger-in signal 104, the receiver circuitry 110 includes a poly-phase time stamping circuit, such as those circuits described in U.S. patent application Ser. No. 11/292,477, entitled “TIME STAMPING EVENTS TO FRACTIONS OF A CLOCK CYCLE,” assigned to common assignee, Agilent Technologies, the entire disclosure of which is hereby incorporated by reference. Likewise, the delay circuitry 112 includes a poly-phase trigger circuit, such as those circuits described in U.S. patent application Ser. No. 11/292,472, entitled “TRIGGERING EVENTS AT FRACTIONS OF A CLOCK CYCLE,” assigned to common assignee, Agilent Technologies; the entire disclosure of which is hereby incorporated by reference in its entirety. In other embodiments, the receive circuitry 110 or the delay circuitry 112 is a chain of gates.

The devices, circuits, circuitry, or components described herein are arranged to be in electrical communication with other devices, circuits, circuitry, or components using any type of suitable data connection that allows the devices to interoperate, regardless of whether the data connection is wired or wireless. Also, all devices described herein may be functions of a microprocessor, microcontroller, or other electrical device, embodied in a discrete component or integrated into an Application Specific Integrated Circuit (ASIC), Field Programmable Gate Array (FPGA), or the like, that are operable to perform the functions described herein. The signals and the circuitry that receives, manipulates, delays, or outputs the signals may do so in any format or technology.

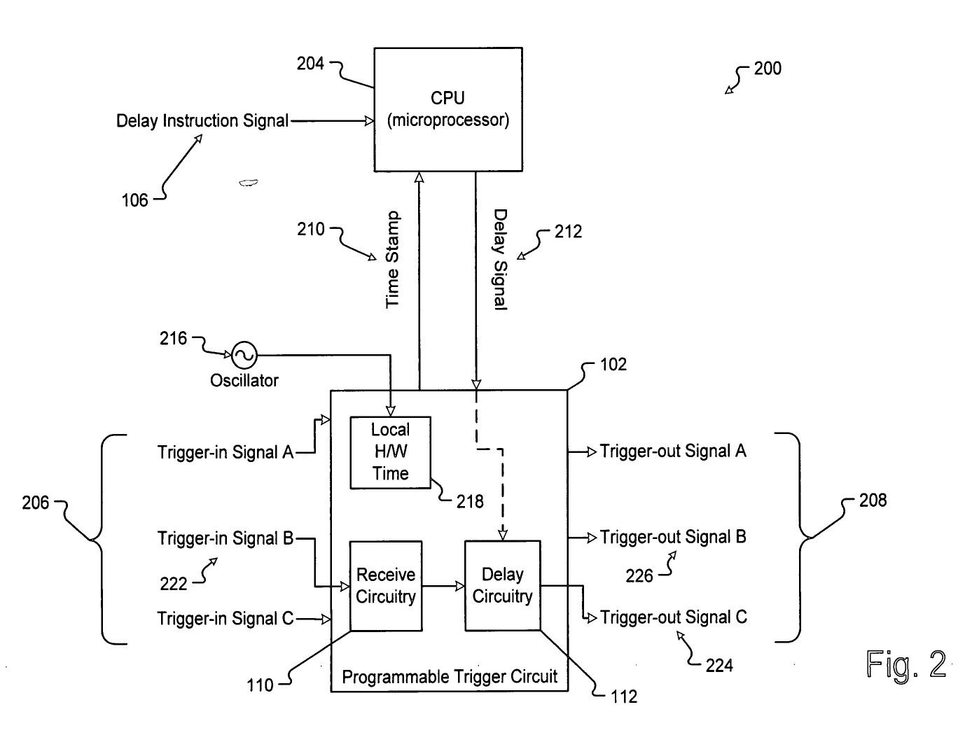

Another exemplary embodiment of a trigger delay circuit 200 is shown in FIG. 2. The programmable trigger circuit 102 is in electrical communication with a central processing unit (CPU) 204. The programmable trigger circuit 102 receives one or more trigger-in signals 206 and time stamps the trigger-in signals 206. The time-stamps 210 are sent to the CPU 204. The CPU 204 sends a delay signal 212 to the programmable trigger circuit 102 to configure the delay circuitry 112 to delay the output of the one or more trigger-out signals 208 on a certain pin or channel. Upon waiting a predetermined amount of time in response to the delay signal 212, the delay circuitry 112 outputs or sends the trigger-out signal 208.

In one embodiment, the delay signal 212 is a preprogram signal. The preprogram delay signal 212 preprograms the programmable trigger circuit 102 to output a trigger-out signal 208 some predetermined amount of delay after receiving a trigger-in signal 206. The preprogram delay signal is sent to the preprogram delay signal 212 to the programmable trigger circuit 102 before the trigger-in signal arrives. In another embodiment, the delay signal 212 represents a “time bomb.” In this exemplary embodiment, the delay signal represents a time at which the trigger-out signal 208 should be sent. The time is within the resolution of a local hardware time 218. The delay circuitry 112 determines an amount of delay and outputs the trigger-out signal 208 at the time specified by the time bomb delay signal 212.

The delay signal 212 in the exemplary embodiment contains one or more signals and/or one or more items of information. For example, the delay signal 212 provides the delay information. The delay information, in one embodiment, includes one or more signals that specify the amount of predetermined delay to wait before sending the output trigger signal 208. The delay information, in one embodiment, specifies delays to a fraction of the clock cycle and/or to multiples of the clock cycle.

In the exemplary embodiment, the CPU 204 receives a delay instruction signal 106 and determines if the delay should be executed by software in the CPU 204 or in hardware on the programmable trigger circuit 102. In the exemplary embodiment, a stable oscillator 216 sends an oscillating signal to a local hardware time circuit 218. The local hardware time circuit 218 maintains a revolving clock based on the predetermined frequency of the oscillating signal and having a predetermined duration. For example, the local hardware time, in one embodiment, is a clock having a frequency of 200 MHz that resets every 90 minutes.

The CPU 204, in one embodiment, receives the time stamp 210 and the delay instruction signal 106, which contains information pertaining to when the trigger-out signal 208 is to be output. The delay instruction signal 106 provides the information required to know either the amount of delay required or the output time for some trigger-in signal 206. In the exemplary embodiment, the delay instruction signal 106 signal is received instructing the programmable trigger delay circuit 200 when, in time, the trigger-out signal 208 should be sent. The signal is received, in the exemplary embodiment, before the trigger-in signal 206. In the exemplary embodiment, the CPU 204 uses the information in the delay instruction signal 106 to resolve an amount of delay required from the receipt of the trigger-in signal 206 until the output of the trigger-out signal 208. The amount of delay is then incorporated into the delay signal 212 for input into the delay circuitry 112.

In other embodiments, the desired delay is minimal, and the programmable trigger circuit 102 receives the delay signal 212 before the trigger-in signal 206 is received. The CPU 204 configures the programmable trigger circuit 102 to automatically delay the output of the trigger-out signal 208 in the hardware of the delay circuitry 112 before receiving the trigger-in signal 206 and without sending information from the programmable trigger circuit 102 to the CPU 204. The delay circuitry 112 delays the amount of time specified then outputs the trigger-out signal 208. Thus, when delay is too short to have the CPU 204 control the delaying of the trigger, the programmable trigger circuit 102 solely delays the trigger signal.

In the exemplary embodiment, if the trigger-out signal 208 is to be delayed more than duration of the hardware clock, for example, more than 90 minutes, the CPU 204 will determine that the CPU software should delay the trigger-out signal 208 for at least a portion of the delay. Once the remaining delay is within the duration of the local hardware time 218, the CPU 204, in one embodiment, sends the delay signal 212 to the programmable trigger circuit 102 to complete the remaining delay. In contrast, if the trigger-out signal 208 should be delayed less than the duration of the local hardware clock 218, the CPU 204 determines to send the delay signal 212 to the delay circuitry 112, to delay the trigger-out signal 208 without completing any delay within the CPU 204.

The programmable trigger circuit 102, in further embodiments, functions as a cross point switch. As such, any trigger-in signal 206 received on any port or channel can be output as any trigger-out signal 208 on any output port or channel. For example, the cross point switch changes the channel from input to output such that a trigger-in signal B 222 is delayed but output as trigger-out signal C 224, rather than trigger-out signal B 226.

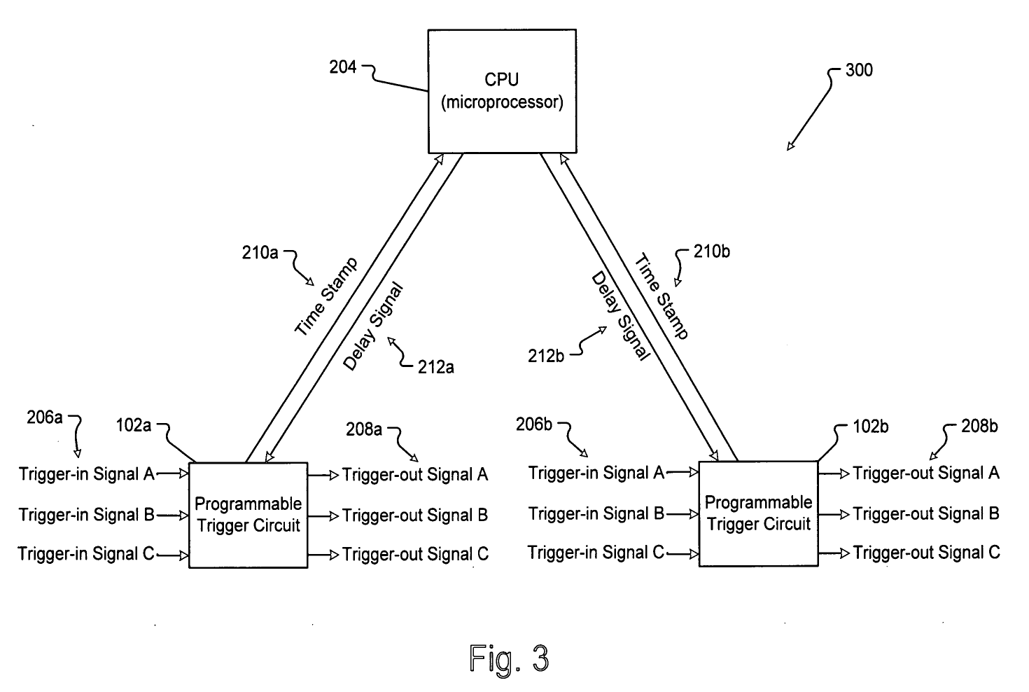

Another exemplary embodiment of a trigger delay circuit 300 is shown FIG. 3. In the exemplary embodiment, a first programmable trigger circuit 102a and a second programmable trigger circuit 102b are each in electrical communication with a CPU 204. Each programmable trigger circuit 102a and 102b receive one or more trigger-in signals 206a and 206b respectively and output one or more trigger-out signals 208a and 208b respectively. The programmable trigger circuits 102a and 102b receive the same or different trigger-in signals and output the same or different trigger-out signals. Both programmable trigger circuits 102a and 102b send a time stamp 210a and 210b to the CPU 204 and receive delay signals 212a and 212b. In the exemplary embodiment, a trigger-in signal 206a received from programmable trigger circuit 102a are delayed and output as trigger-out signal 208b by programmable trigger circuit 102b and vice versa.

The trigger delay circuit 300 allows for more flexible delay of trigger signals. Programmable trigger circuit 102a is operable to delay trigger signals in a certain time range while programmable trigger circuit 102b is operable to delay trigger signals in a different time range. In addition, if one programmable trigger circuit is already delaying its maximum amount of signals, the CPU 204 has another programmable trigger circuit delay newly received trigger signals. The trigger delay circuit 300 has more than two programmable trigger circuits, further enhancing the flexibility of the time of delay.

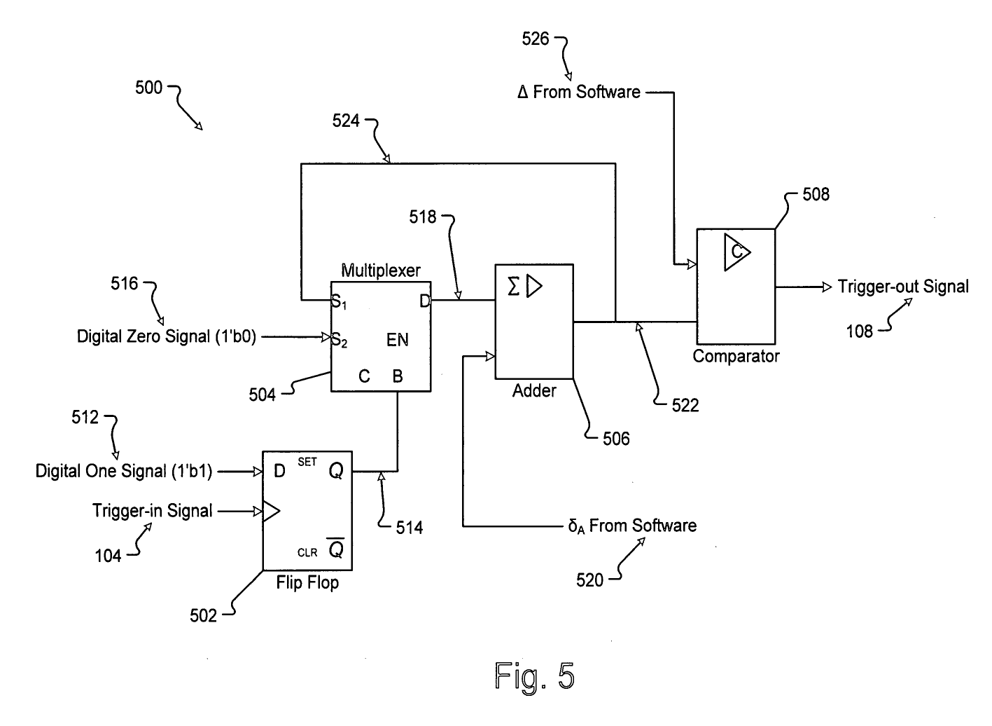

Further aspects include one or more hardware systems that are operable to function as a delay circuitry 112. In one exemplary embodiment, a delay circuitry 500 is shown in FIG. 5. The delay circuitry 500 includes a flip flop 502 that receives a constant digital high signal (digital 1 (one)) 512 and receives a trigger-in signal 104. In one embodiment, the trigger-in signal 104 is a trigger-in signal directly input into a programmable trigger circuit, such as signal 206 (FIG. 4), or as trigger-in signal that is part of a delay signal from a CPU, such as signal 212 (FIG. 4). After the trigger-in signal 104 is received, the flip flop 502 outputs a signal 514 to a multiplexer 504 in electrical communication with the flip flop 502.

The multiplexer 504 receives a digital low signal 516, and, upon being enabled by signal 514, the multiplexer 504 outputs a signal 518 to a digital adder 506 in electrical communication with the multiplexer 504. The adder 506 outputs a signal that is feedback 524 to the multiplexer 504. This connection between the multiplexer 504 and the adder 506 allows for recursive addition. A CPU, such as CPU 204 (FIG. 4), sends a first delay signal 520 (δ_{A} from software) to the adder 506, as part of a delay signal, such as delay signal 212 (FIG. 4), that generates a certain delay across the multiplexer/adder circuits. The CPU will, by measurement, know the amount of delay across the multiplexer 504 and adder 506 for each recursive addition. The amount of delay increases as the bit-width of the number being added increases. In the exemplary embodiment, the adder 506 outputs a value only when the addition is completed to prevent time misalignment between the least significant bits and most significant bits.

The adder 506 also outputs a signal 522 to a comparator 508 in electrical communication with the adder 506. The comparator 508 compares the output signal 522 to a second delay signal 526 (the delta signal (Δ)) from the CPU, again as part of a delay signal, such as delay signal 212 (FIG. 4). Once the two signals 522 and 526 compare, the comparator 508 outputs the trigger-out signal 108. As such, the delay circuitry 500 outputs a delayed trigger-out signal 108 independent of the clock and as a function of the gate delays across the multiplexer 504, adder 506 and comparator 508. Mathematically, the amount of delay is represented by equation (1), which follows:
Total_Delay=(Number_of_Additions*(δ_{Multiplexer}+δ_{Adder}))+δ_{Comparator} (1)
where, Total_Delay represents the total amount of delay that occurs between the reception of the trigger-in signal and the output of the trigger-out signal, Number_of_Additions represents the number of recursive additions completed across the multiplexer and adder, δ_{Multiplexer} equals the gate delay for the multiplexer, δ_{Adder} equals the average gate delay for the Adder and δ_{Comparator} equals the delay for the comparator.

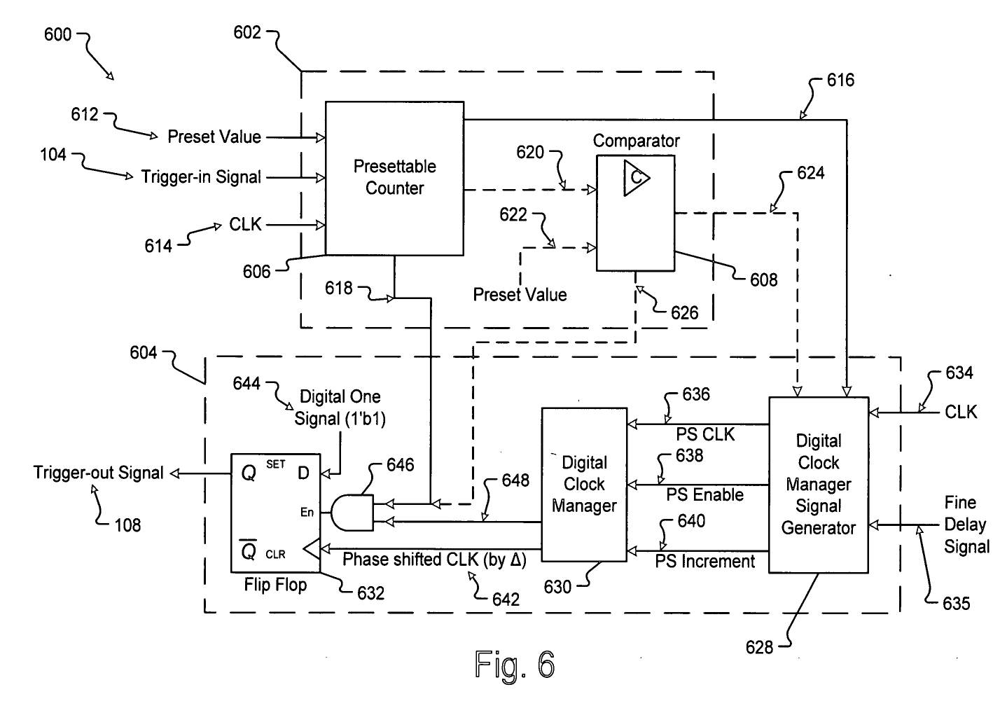

Another exemplary embodiment of a delay circuitry 600 is shown in FIG. 6. In the exemplary embodiment, the delay circuitry 600 has a coarse delay circuit 602 and a fine delay circuit 604. In one embodiment, the coarse delay circuit 602 includes only a presettable counter 606. The presettable counter 606 receives a stable oscillating signal or clock (CLK) 614, a trigger-in signal 104 and a preset value 612. The preset value 612 is input from a CPU, such as CPU 204 (FIG. 4), as part of a delay signal, such as delay signal 212 (FIG. 4). In one embodiment, upon receiving the trigger-in signal 104, the presettable counter 606 begins counting the clock cycles of the CLK signal 614 until it reaches the input preset value 612. When the count reaches the preset value 612, the presettable counter 606 outputs a signal 616 to the fine delay circuit 604. In another embodiment, upon receiving the trigger-in signal 104, the presettable counter 606 sets the counter to the value of the preset value 612. When the count reaches zero, the presettable counter 606 outputs a signal 616 to the fine delay circuit 604. In addition, the presettable counter 606 sends an enable signal 618 to an AND gate 646 that can enable a flip flop 632 to output the trigger-out signal 108.

In another exemplary embodiment, the coarse delay circuit 602 includes a presettable counter 606 in electrical communication with a comparator 608. The presettable counter 606, in this exemplary embodiment, receives the trigger-in signal 104 and the CLK 614. Upon receiving the trigger-in signal 104, the presettable counter 606 again begins counting the clock cycles of the CLK signal 614. In the exemplary embodiment, the presettable counter 606 outputs the count 620, i.e., the number of clock cycles that have elapsed, to the comparator 608. The comparator 608 compares the count 620 to a preset value signal 622. If the count 620 compares to the preset value 622, the comparator 608 outputs signal 624 to the fine delay circuit 604. In this way, the coarse delay circuit 602 delays the trigger-out signal 108 by some number of clock cycles of the CLK 614. The comparator 608 also sends out an enable signal 626 to an AND gate 646 that can enable a flip flop 632 to output the trigger-out signal 108.

The fine delay circuit 604 includes a digital clock manager signal generator 628 in electrical communication with a digital clock manager 630, which is in turn in electrical communication with a flip flop 632. The digital clock manager signal generator 628 receives the output signal, either signal 616 or 624 from the coarse delay circuit 602. In addition, the digital clock manager signal generator 628 receives a clock signal 634, and a fine delay signal 635 from a CPU, such as CPU 204 (FIG. 4), as part of a delay signal, such as delay signal 212 (FIG. 4). Upon receiving input signal 616 or 624, the digital clock manager signal generator 628 outputs a phase shift CLK (PS CLK) 636, a phase shift enable (PS Enable) signal 638 and a phase shift increment (PS Increment) signal 640. The PS CLK 636, PS Enable 638 and the PS Increment 640 signals instruct the digital clock manager 630 to output a phase shifted clock (Phase shifted CLK (by Δ)) signal 642 having a certain phase shift. The digital clock manager 630 also sends an enable signal 648 as the second input into an AND gate 646, which sends an enable signal to the flip flop 632 when both the enable signal 648 and either the enable signal 618 or 626 are high (a digital one).

A constant digital high (digital one) signal 644 and the phase shifted CLK signal 642 are input into the flip flop 632. Upon receiving the phase shifted CLK signal 642 and an enable signal from the AND gate 646, the flip flop 632 outputs the trigger-out signal 108. As such, the trigger-out signal 108 is delayed some fraction of the clock cycle determined by the amount of phase shift programmed by the fine delay signal 635. The combination of the coarse delay circuit 602 and the fine delay circuit 604 allow for large maximum delays that depend on the bit-width of the presettable counter 606 and both fine time resolution and small minimum delays that depend on the number of phases by which the PS CLK 636 can be shifted.

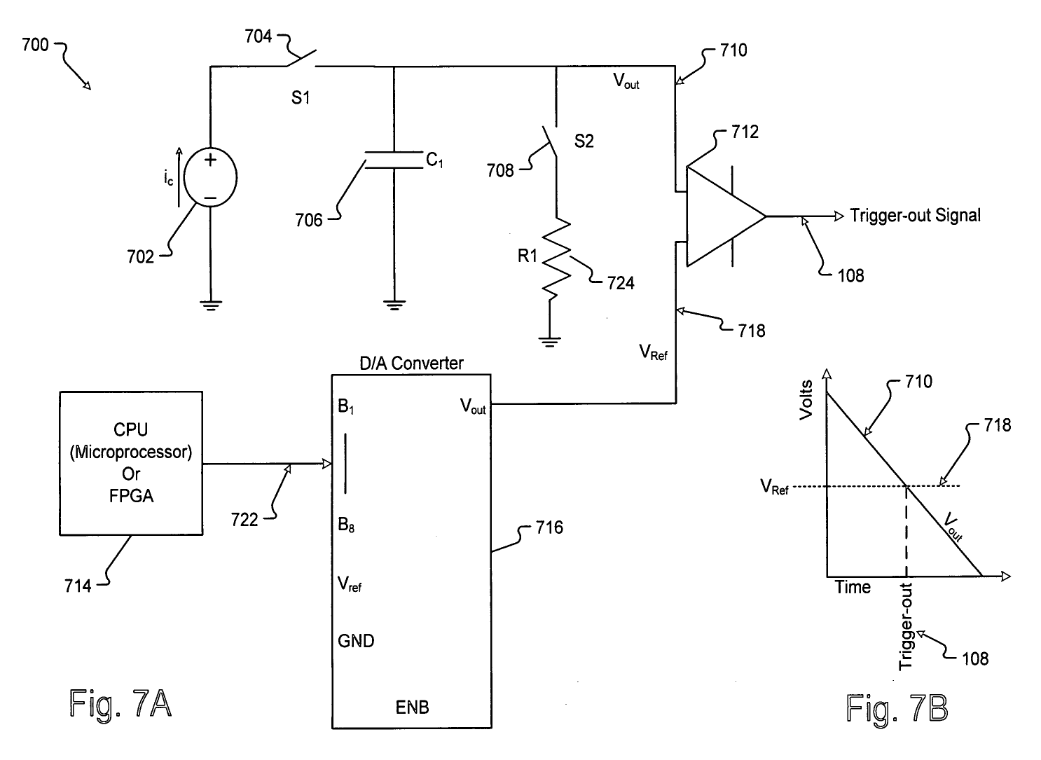

Another embodiment of a delay circuitry 700 is shown in FIG. 7A, and the function of the circuit 700 is represented in FIG. 7B. The delay circuitry 700 mixes analog and digital circuitry. In embodiments, the delay circuit 700 is a fine delay circuit that delays the output of a trigger-out signal 108 to fractions of a clock cycle. A constant current source 702 is in electrical communication with a first switch S1 704. Switch S1 704 is controlled by a CPU, such as CPU 204 (FIG. 4), that close and open the switch S1 704 for predetermined durations of a clock cycle, as directed by a delay signal, such as delay signal 212 (FIG. 4). At some predetermined time, switch S1 704 is closed, and the constant current source 702 charges capacitor C₁ 706 for a predetermined number of clock cycles. The CPU determines the amount of charge on capacitor C₁ 706 by knowing the capacitance of the capacitor C₁ 706, the amount of current provided by the constant current source and the duration or number of clock cycles the capacitor C₁ 706 was charged. After the capacitor is charged, switch S1 704 is opened and a second switch S2 708 is closed. The capacitor C₁ 706 discharges through resistor R1 724 at a constant and known rate. Vout 710, which is equivalent to the charge on the discharging capacitor C₁ 706 divided by the capacitance of C₁ 706 is input into an operation amplifier 712.

A CPU 714 provides a digital signal 722 to a digital to analog converter 716. In the exemplary embodiment, the digital to analog converter 716 is an 8-bit D/A converter, but other D/A converters are possible that convert digital inputs 722 having more or fewer bits, such as a four-bit digital input or a 32-bit digital input. The D/A converter 716 provides the analog VRef signal 718 to the operation amplifier 712. As shown in FIG. 7B, when the Vout signal 710 is the same as the VRef signal 718, the operational amplifier 712 outputs the trigger-out signal 108. Thus, by knowing the discharge rate of the capacitor C₁ 706 through resistor R1 724 and appropriately setting the VRef signal 718, the delay circuitry 700 can delay the trigger-out signal 108 by any amount of time. The delay is as fine as the bit width of the D/A converter 716 and the discharge rate of the capacitor C₁ 706 through resistor R1 724.

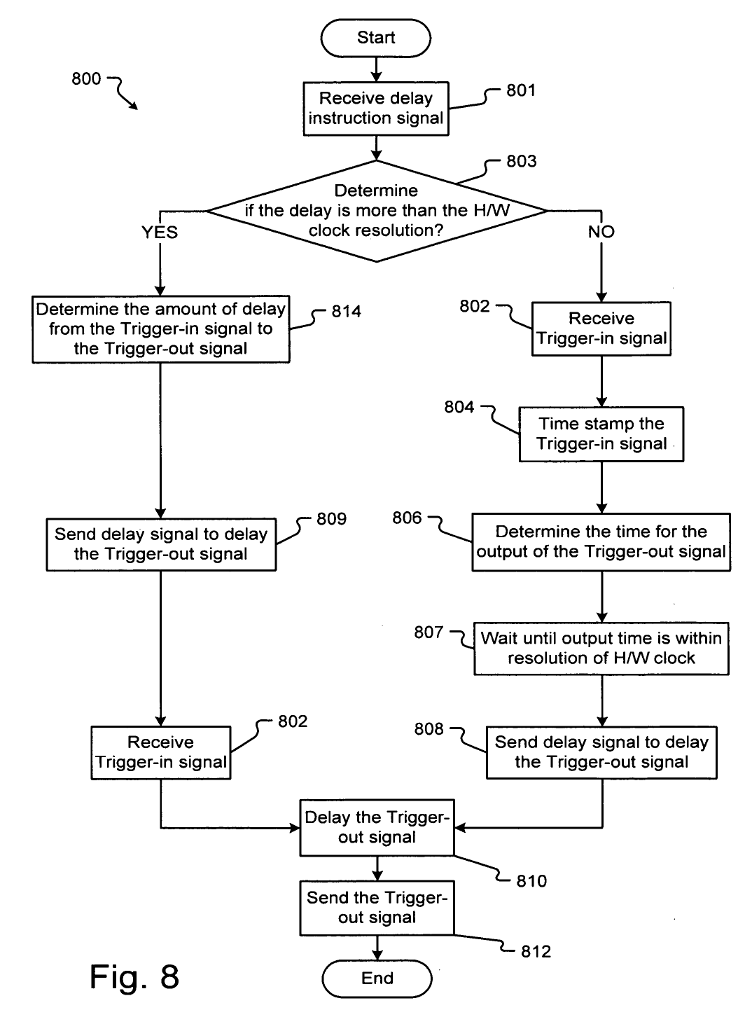

A method 800 for delaying the trigger of a signal is shown in FIG. 8. Receive operation receives a delay instruction signal, such as delay instruction signal 106 (FIG. 1). The delay instruction signal instructs a CPU, such as CPU 204 (FIG. 2), or other circuitry at which time a trigger-out signal, such as trigger-out signal 108, should be sent or the delay between a trigger-in signal, such as trigger-in signal 104, and a trigger-out signal. Determine operation 803 determines if the delay required according to the delay instruction signal is within the resolution of the hardware clock, such as hardware clock 218 (FIG. 2). For example, if the hardware clock is a revolving 90 minute clock, then all delays within 90 minutes are within the resolution of the hardware clock.

If the required delay is not within the resolution of the hardware clock, the process 400 flows NO to receive operation 802. Receive operation 802 receives a trigger-in signal, such as trigger-in signal 104 (FIG. 1). Time stamp operation 804 time stamps the trigger-in signal. In the exemplary embodiment, a programmable trigger circuit, such as programmable trigger circuit 102 (FIG. 1), receives and time stamps the trigger-in signal. In addition, the programmable trigger circuit sends the time stamp to a CPU.

Determine operation 806 determines the time at which the trigger-out signal is to be output. Wait operation 807 waits until the time at which the trigger-out signal is to be output is within the resolution of the hardware clock. If the amount of time between the current time and the time for output is longer than the resolution of the hardware clock, the CPU waits to send a delay signal, such as delay signal 212 (FIG. 2), to the programmable trigger circuit. For example, if the time for output is 11:30 and the current time is 7:00, the amount of time until the trigger-out signal is to be sent is 270 minutes. The CPU would wait until the 270 minutes is reduced to 90 minutes before sending the delay signal.

Send operation 808 sends a delay signal, such as delay signal 212 (FIG. 2), to output the trigger-out signal, such as trigger-out signal 108 (FIG. 1). In the exemplary embodiment, the CPU sends a delay signal to the programmable trigger circuit if the amount of delay is within the duration of the local hardware clock time.

If the required delay is not within the resolution of the hardware clock, the process flows YES to determine operation 814. Determine operation 814 determines an amount of delay required between the trigger-in signal and the trigger-out signal. In the exemplary embodiment, the delay between the trigger-in signal and the trigger-out signal requires the programmable trigger circuit to be preprogrammed. Thus, send operation 809 sends a delay signal to the programmable trigger circuit. In the exemplary embodiment, the CPU sends a delay signal to the programmable trigger circuit to set-up the programmable trigger circuit to delay the trigger-out signal a predetermined amount of time upon receipt of the trigger-in signal. Receive operation 802 receives the trigger-in signal, similar to receive operation 802 described previously.

Delay operation 810 delays the output of the trigger-out signal. The programmable trigger circuit is operable to wait a predetermined amount of time before outputting the trigger-out signal. The programmable trigger circuit uses any type of delay circuitry, such as delay circuitry 500 (FIG. 5), 600 (FIG. 6) or 700 (FIG. 7). In one embodiment, the programmable trigger circuit waits a predetermined delay specific in a delay signal sent in send operation 809. In other embodiments, the programmable trigger circuit determines an amount of delay to wait before sending the trigger-out signal at a predetermined time specified in a delay signal sent after send operation 808. The programmable trigger circuit waits the determined delay. After delaying for some predetermined amount of time, send operation 812 sends the trigger-out signal.

The various embodiments described above are provided by way of illustration only and should not be construed to limit the scope of the appended claims. Those skilled in the art will readily recognize various modifications and changes that may be made without following the example embodiments and applications illustrated and described herein, and without departing from the true spirit and scope of the following claims.

What is claimed is:

1. A trigger delay circuit, comprising:
a receive circuitry operable to receive a trigger-in signal; and
a delay circuitry in electrical communication with the receive circuitry, the delay circuitry operable to determine a predetermined time delay based on a delay instruction signal and delaying, from the time the trigger-in signal is received, for the predetermined time delay, then outputting a trigger-out signal.

2. A trigger delay circuit as defined in claim 1, further comprising:
a central processing unit in electrical communication with the receive circuitry and the delay circuitry, the central processing unit operable to receive the delay instruction signal, determine a delay for the trigger-out signal based on the delay instruction signal, the central processing unit operable to provide a delay signal including the determined delay to the delay circuitry to delay the output of the trigger-out signal.

3. A trigger delay circuit as defined in claim 2, further comprising:
one or more other receive circuitry in electrical communication with the central processing unit, the one or more other receive circuitry operable to receive one or more other trigger-in signals; and
one or more other delay circuitry in electrical communication with the central processing unit; the one or more other delay circuitry operable to produce one or more other trigger-out signals, the one or more other delay circuitry operable to delay output of the one or more other trigger-out signals by some predetermined delay different than the delay circuitry.

4. A trigger delay circuit as defined in claim 1, further comprising:
a central processing unit in electrical communication with the receive circuitry and the delay circuitry, the central processing unit operable to receive the delay instruction signal, determine an output time at which the trigger-out signal is to be sent, the central processing unit operable to provide a delay signal including the determined time to the delay circuitry to delay the output of the trigger-out signal.

5. A trigger delay circuit as defined in claim 4, wherein
the receive circuitry is operable to time stamp the trigger-in signal and send the time stamp to the central processing unit;
the central processing unit is operable to receive the delay instruction signal providing the output time when to output the trigger-out signal; and
the central processing unit is operable to determine the whether the amount of time between the time stamp and the output time is longer than a duration for a hardware clock input into the delay circuitry.

6. A trigger delay circuit as defined in claim 5, wherein the delay circuitry further comprises:
a local hardware clock circuit operable to receive a clock signal, the local hardware clock circuit operable to provide a local hardware clock to the delay circuitry;
wherein the local hardware clock has a predetermined frequency and a predetermined duration; and
wherein the central processing unit completing at least a portion of the delay if the amount of time between the time stamp and the output time is greater than the duration of the local hardware clock.

7. A trigger delay circuit as defined in claim 1, wherein the delay circuitry is operable as a cross point switch, wherein a trigger-in signal received on a first channel in the receive circuitry is output as a trigger-out signal on a second channel.

8. A trigger delay circuit as defined in claim 1, wherein the delay circuitry comprises:
a coarse delay circuit to delay the trigger-out signal a first amount of time, the coarse delay circuit operable to output a coarse delay signal; and
a fine delay circuit in electrical communication with the coarse delay circuit, to delay the trigger-out signal a second amount of time, the fine delay circuit operable to output the trigger-out signal.

9. A trigger delay circuit as defined in claim 8, wherein the coarse delay circuit comprises:
a presettable counter, the presettable counter operable to receive the trigger in signal and a preset value signal in the delay signal and count for a predetermined amount of time associated with the preset value, the presettable counter operable to output the coarse delay signal when the predetermined amount of time has been counted.

10. A trigger delay circuit as defined in claim 8, wherein the coarse delay circuit comprises:
a presettable counter, the presettable counter operable to receive the trigger in signal and count for a predetermined amount of time, the presettable counter operable to output a count signal; and
a comparator in electrical communication with the presettable counter, the comparator operable to compare the count signal to a preset value received in the delay signal, the comparator operable, if the count signal and the preset value are the same, to output the coarse delay signal.

11. A trigger delay circuit as defined in claim 8, wherein the fine delay circuit comprises:
a digital clock manager signal generator in electrical communication with the coarse delay circuit, the digital clock manager signal generator operable to receive the coarse delay signal and output one or more phase shift signals in response to the delay signal; and
a digital clock manager in electrical communication with the digital clock manager signal generator, the digital clock manager operable to output a phase-shifted clock in response to the one or more phase shift signals from the digital clock manager signal generator, the digital clock manager outputting a phased shifted clock.

12. The trigger delay circuit as defined in claim 11, further comprising a flip flop in electrical communication with the digital clock manager, the flip flop operable to output the trigger-out signal in response to the phase shifted clock.

13. The trigger delay circuit as defined in claim 1, wherein the delay circuitry comprises:
a flip flop, the flip flop operable to receive the trigger-in signal from the receive circuit;
a multiplexer in electrical communication with the flip flop, the multiplexer operable to output a multiplexer signal multiplexed from a first input and a second input, wherein the second input is a digital zero; and
an adder in electrical communication with the multiplexer, the adder operable to add a delay value from the delay signal to the multiplexer signal, the adder outputting an adder signal, the adder signal being input to the multiplexer as the first input.

14. The trigger delay circuit as defined in claim 1, wherein the trigger circuit further comprises a comparator in electrical communication with the adder, the comparator operable to compare the adder signal to a delta signal from the delay signal, the comparator operable to output the trigger-out signal if the adder signal compares to the delta signal.

15. The trigger delay circuit as defined in claim 1, wherein the delay circuitry comprises:
a first voltage source providing a first voltage, including:
a constant current source, operable to provide a constant current;
a first switch in electrical communication with the constant current source;
a second switch in electrical communication with the constant current source through the first switch;
a resistor in electrical communication with the constant current source through the second switch, the resistor having a predetermined resistance;
a capacitor in electrical communication with to the constant current source through the first switch and in electrical communication with the resistor, the capacitor charging to a predetermined voltage when the first switch is closed, the capacitor discharging at a predetermined rate through the resistor when the first switch is opened and the second switch is closed to create a charge across the capacitor at a predetermined time, wherein the charge is equivalent to the first voltage;
a second voltage source providing a reference voltage, including:
a central processing unit, the central processing unit operable to determine a time to output the trigger-out signal and output a digital signal;
a digital to analog converter in electrical communication with the central processing unit, the digital to analog converter operable to convert the digital signal into the reference voltage; and
an operational amplifier in electrical communication with the first voltage source and the second voltage source, the operational amplifier operable to output the trigger-out signal when the first voltage and the reference voltage are equivalent.

16. A method for delaying a trigger signal, comprising:
receiving a trigger-in signal;
determining a delay from receipt of the trigger-in signal and output of a trigger-out signal;
sending a delay signal to delay the trigger-out signal according to the determined delay;
in response to the delay signal, delaying the output of the trigger-out signal; and
sending the trigger-out signal after the determined delay.

17. A method as defined in claim 16, wherein receiving the trigger-in signal further comprises time stamping the trigger-in signal.

18. A method as defined in claim 17, wherein determining a delay further comprises:
receiving a delay instruction signal providing a time when to output the trigger-out signal; and
calculating the delay between the time stamp and the time when to output the trigger-out signal.

19. A method as defined in claim 18, further comprising:
comparing the delay to a duration for a local hardware clock;
if the delay is larger than the duration, delaying, for at least a portion of the delay, the output of the trigger-out signal in a central processing unit.

20. A programmable trigger circuit, comprising:
a CPU, the CPU operable to receive a delay instruction signal providing a time at which a trigger-out signal is to be output, the CPU operable to send a delay signal in response to the delay instruction signal; and
one or more programmable trigger circuits in electrical communication with the CPU, the programmable trigger circuits including:
a receive circuitry to receive a trigger-in signal;
a delay determination circuitry in electrical communication with the receive circuitry, the delay determination circuitry operable to receive the delay signal and determine a delay from the receipt of the trigger-in signal to an output of the trigger-out signal; and
an output circuitry in electrical communication with the delay determination circuitry, the output circuitry operable to output the trigger-out signal after the determined delay.
